(19) United States
(12) Patent Application Publication
(10) Pub. No.: US 2007/0284681 A1
(43) Pub. Date: Dec. 13, 2007

(54) APPARATUS AND METHOD FOR PROTECTIVE COVERING OF MICROELECTROMECHANICAL SYSTEM (MEMS) DEVICES

(75) Inventors: Jean-Louis Massieu, Montauban (FR); Harley K. Heinrich, Snohomish, WA (US)

Correspondence Address: SEED INTELLECTUAL PROPERTY LAW GROUP PLLC, 701 FIFTH AVENUE, SUITE 5400, SEATTLE, WA, 98104-7092, US

(73) Assignee: INTERMEC IP CORP., Everett, WA (US)

(21) Appl. No.: 11/761,946

(22) Filed: Jun. 12, 2007

Related U.S. Application Data
(60) Provisional application No. 60/813,097, filed on Jun. 12, 2006.

(51) Int. Cl. H01L 23/48; H01L 21/00

(52) U.S. Cl. 257/415; 438/51; 438/456; 438/113; 257/704

(57) ABSTRACT

A microelectromechanical system (MEMS) assembly includes a MEMS substrate having a plurality of MEMS devices, a plurality of bond pads, and a wafer cap. The wafer cap includes a unitary structure having a plurality of pockets and a plurality of apertures. The wafer cap is fixed to the MEMS substrate such that at least some of the MEMS devices are enclosed within respective enclosed cavities formed by the pockets and the MEMS substrate, and such that at least come of the apertures provide access to the bond pads from an exterior of the wafer cap.

### CROSS-REFERENCE TO RELATED APPLICATION

This application claims the benefit under 35 U.S.C. § 119(e) of U.S. Provisional Patent Application No. 60/813,097 filed Jun. 12, 2006, which is incorporated herein by reference in its entirety.

### BACKGROUND OF THE INVENTION

1. Field of the Invention

This description generally relates to the field of semiconductor manufacturing, and more particularly to the manufacture of microelectromechanical systems (MEMS), for example MEMS micro-mirrors.

2. Description of the Related Art

MEMS devices, for example MEMS micromirrors, are currently being used in applications including optical switching in fiber optic networks, maskless EUV (Extreme Ultraviolet) lithography, and projection display devices. The micromirrors used in those applications are actuated to precise positions and/or frequencies during use.

The small size of MEMS devices, which makes them suitable for optical switching, is also a weakness, rendering such devices susceptible to damage during manufacture and/or use. MEMS devices are sensitive to hazards such as shock, or contamination by dust, other particles, and/or moisture. Functional defects may result from one or more of such hazards, or by physical scratching or other such damage that occurs at the surface of the MEMS device. Additionally, or alternatively, contamination may degrade or render the MEMS device inoperative, particularly where the MEMS device is an optical device such as a micro-mirror. Device damage due to any one of such hazards may occur during dicing as well as during packaging, which are known to significantly adversely effect yields of the manufacturing process.

To protect against potentially destructive hazards, MEMS devices may be protected during dicing and packaging. One technique, disclosed in U.S. Pat. No. 6,534,340, includes bonding a protective semiconductor wafer to the MEMS substrate before dicing the MEMS substrate into individual MEMS devices. The protective wafer is bonded to the MEMS substrate using a pattern of glass-like “posts” or “frit glass” as a bonding agent. In such a technique, the MEMS devices are hermetically sealed inside an open cavity formed by the frit glass pattern, the MEMS substrate and the protective wafer. This technique involves precision patterning of the frit glass pattern so as to avoid the frit glass adhesive from underfilling the protective wafer and leaving essentially no open cavity to allow useful movement of the MEMS devices.

Another known technique, disclosed in U.S. Pat. No. 6,946,326, includes forming a removeable protective wafer that is mounted on the MEMS substrate prior to dicing and removed after packaging. The removeable protective wafer includes recessed cavities located over each MEMS device site, which contains the MEMS device and bond sites or pads. The bond pads will only be exposed and accessible to electrical connections after the protective wafer is removed. Once the protective wafer is removed the MEMS devices and the bond pads are exposed and the MEMS devices are once again vulnerable to damage.

In yet another known technique, disclosed in U.S. Pat. No. 6,846,692, the MEMS devices are interposed in one or more sacrificial layers that are in direct contact with the underlying MEMS devices, thereby providing no space for movement of the MEMS devices. The sacrificial layers are removed by standard etching techniques that are known in the art. Etching of the sacrificial layers induces stress onto the MEMS devices.

It is therefore desirable to have new methods and apparatus that provide protection of the MEMS devices during dicing and packaging while ensuring useful movement and electrical access to the MEMS devices.

### BRIEF SUMMARY OF THE INVENTION

According to one aspect, a method of producing a microelectromechanical system (MEMS) device includes providing a MEMS substrate having a first face and a second face opposed to the first face, a plurality of micro electro-mechanical (MEMS) structures, and a plurality of bond pads, at least some of the bond pads electrically coupled to at least some of the MEMS structures, providing a wafer cap in the form of a unitary structure having an inner face, an outer face opposed to the inner face, a plurality of pockets formed in the inner face and a plurality of apertures extending through the unitary structure from the outer face to the inner face, each of the plurality of apertures laterally spaced from any adjacent ones of the pockets, and fixing the inner face of the wafer cap to the first face of the MEMS substrate such that at least some of the MEMS structures are enclosed within respective enclosed cavities formed by the pockets and the MEMS substrate, and such that at least some of the apertures of the wafer cap provide access to the bond pads of the MEMS substrate from an exterior of the wafer cap.

According to one aspect, a microelectromechanical system (MEMS) device includes a MEMS substrate having a first face and a second face opposed to the first face, a plurality of micro electro-mechanical structures, and a plurality of bond pads, at least some of the bond pads electrically coupled to at least some of the MEMS structures, and a wafer cap in the form of a unitary structure having an inner face, an outer face opposed to the inner face, a plurality of pockets formed in the inner face and a plurality of apertures extending through the unitary structure from the outer face to the inner face, each of the plurality of apertures laterally spaced from any adjacent pockets, wherein the inner face of the wafer cap is fixed to the first face of the MEMS substrate such that at least some of the MEMS mirror structures are enclosed within respective enclosed cavities formed by the pockets and the MEMS substrate, and such that at least some of the apertures of the wafer cap provide access to the bond pads of the MEMS substrate from an exterior of the wafer cap.

According to another aspect, a microelectromechanical system (MEMS) device includes a MEMS substrate having a first face and a second face opposed to the first face, a plurality of micro electro-mechanical oscillateable micro-mirror structures, and a plurality of bond pads, at least some of the bond pads electrically coupled to at least some of the MEMS structures, and a wafer cap in the form of a unitary structure transmissive of light in an optical portion of the electromagnetic spectrum and having an inner face, an outer face opposed to the inner face, a plurality of pockets formed in the inner face and a plurality of apertures extending through the unitary structure from the outer face to the inner face, each of the plurality of apertures laterally spaced from any adjacent pockets, wherein the inner face of the wafer cap is fixed to the first face of the MEMS substrate such that at least some of the MEMS micro-mirror structures are enclosed within respective enclosed cavities formed by the pockets and the MEMS substrate with sufficient space to oscillate therein, and such that at least some of the apertures of the wafer cap provide access to the bond pads of the MEMS substrate from an exterior of the wafer cap.

According to one aspect, a method of producing a microelectromechanical system (MEMS) device includes providing a MEMS substrate having a first face and a second face opposed to the first face, a plurality of micro electro-mechanical (MEMS) structures, and a plurality of bond pads, at least some of the bond pads electrically coupled to at least some of the MEMS structures; providing a wafer cap in the form of a unitary glass structure having an inner side, an outer side opposed the inner side, the wafer cap pre-patterned with a first plurality of apertures extending through the unitary glass structure from the outer side to the inner side; providing a wafer cap support structure in the form of a unitary structure having an inner face, an outer face opposed the inner face, the wafer cap support structure pre-patterned with a second and a third plurality of apertures, the second and the third plurality of apertures extending through the unitary structure from the outer face to the inner face; fixing the outer face of the wafer cap support structure to the inner side of the wafer cap such that a plurality of pockets are formed extending between the inner side of the wafer cap and the inner face of the wafer cap support structure; and fixing the inner face of the wafer cap support structure to the first face of the MEMS substrate such that at least some of the MEMS structures are enclosed within respective cavities formed by the pockets and the MEMS substrate, and such that at least some of the first and third apertures provide access to the bond pads of the MEMS substrate from an exterior of the wafer cap.

According to one aspect, a microelectromechanical system (MEMS) device includes a MEMS substrate having a first face and a second face opposed to the first face, a plurality of micro electro-mechanical (MEMS) structures, and a plurality of bond pads, at least some of the bond pads electrically coupled to at least some of the MEMS structures; a wafer cap in the form of a unitary glass structure having an inner side, an outer side opposed the inner side, the wafer cap pre-patterned with a first plurality of apertures extending through the unitary glass structure from the outer side to the inner side; a wafer cap support structure in the form of a unitary structure having an inner face, an outer face opposed the inner face, the wafer cap support structure pre-patterned with a second and a third plurality of apertures, the second and the third plurality of apertures extending through the unitary structure from the outer face to the inner face; and a plurality of pockets formed upon fixing the outer face of the wafer cap support structure to the inner side of the wafer cap, the pockets extending between the inner side of the wafer cap and the inner face of the wafer cap support structure, the inner face of the wafer cap support structure is fixed to the first face of the MEMS substrate such that at least some of the MEMS structures are enclosed within respective cavities formed by the pockets and the MEMS substrate, and such that at least some of the first and third apertures provide access to the bond pads of the MEMS substrate from an exterior of the wafer cap.

According to one aspect, a method of producing a microelectromechanical system (MEMS) device includes providing a MEMS substrate having a first face and a second face opposed to the first face, a plurality of micro electro-mechanical (MEMS) structures, and a plurality of bond pads, at least some of the bond pads electrically coupled to at least some of the MEMS structures; providing a glass wafer cap having a first and a second surface; applying a wafer cap support layer to the first surface of the glass wafer cap; patterning the wafer cap support layer to form a plurality of pockets; adhering the wafer cap support layer to the first face of the MEMS substrate such that at least some of the MEMS structures are enclosed within respective cavities formed by the pockets and the MEMS substrate; applying a masking layer to the second surface of the glass wafer cap; patterning the masking layer to expose portions of the second surface of the glass wafer cap that are in registration with the bond pads; and etching portions of the glass wafer cap and the wafer cap support layer underlying the exposed portions of the glass wafer cap to expose the bond pads.

According to one aspect, a microelectromechanical system (MEMS) device includes a MEMS substrate having a first face and a second face opposed to the first face, a plurality of micro electro-mechanical (MEMS) structures, and a plurality of bond pads, at least some of the bond pads electrically coupled to at least some of the MEMS structures; a glass wafer cap having a first surface and a second surface opposed the first surface; a wafer cap support layer coupled to the first surface of the glass wafer cap; a plurality of pockets formed upon patterning the wafer cap support layer wherein the wafer cap support layer is adhered to the first face of the MEMS substrate such that at least some of the MEMS structures are enclosed within respective cavities formed by the pockets and the MEMS substrate; and a masking layer coupled to the second surface of the glass wafer cap, the masking layer patterned to expose portions of the second surface of the glass wafer cap that are in registration with the bond pads, the bond pads being exposed upon etching portions of the glass wafer cap and the wafer cap support layer underlying the exposed portions of the second surface of the glass wafer cap.

### BRIEF DESCRIPTION OF THE SEVERAL VIEWS OF THE DRAWING(S)

In the drawings, identical reference numbers identify similar elements or acts. The sizes and relative positions of elements in the drawings are not necessarily drawn to scale. For example, the shapes of various elements and angles are not drawn to scale, and some of these elements are arbitrarily enlarged and positioned to improve drawing legibility. Further, the particular shapes of the elements as drawn, are not intended to convey any information regarding the actual shape of the particular elements, and have been solely selected for ease of recognition in the drawings.

FIG. 1 is a partial isometric view of an assembly including a MEMS substrate having a plurality of MEMS devices and protective wafer cap, and a blown up detailed view of a portion of the wafer assembly, according to one illustrated embodiment.

FIG. 2A is a cross-sectional view of the assembly of FIG. 1 prior to application of an adhesive between the wafer cap and the MEMS substrate.

FIG. 2B is a cross-sectional view of the assembly of FIG. 1, showing the adhesive coupling the wafer cap to the MEMS substrate.

FIG. 2C is a cross-sectional view of a plurality of capped dies, according to one illustrated embodiment.

FIG. 3 is a flow diagram of a method of producing a protected microelectromechanical system (MEMS) device, according to one illustrated embodiment.

FIG. 4 is a cross-sectional illustrative view of several stages of the method of FIG. 3.

FIG. 5A is a top plan view of a wafer packaging assembly, according to one illustrated embodiment.

FIG. 5B is a cross-sectional view of the wafer packaging assembly of FIG. 5A taken along section line 5B, according to one illustrated embodiment.

FIG. 5C is a cross-sectional view of an individual assembly, according to one illustrated embodiment.

FIG. 6 is a schematic diagram of respective top plan views of a MEMS substrate, wafer cap, wafer cap support structure, glass cavity seal wafer glue preform, topside wafer preform and MEMS wafer glue preform, according to one illustrated embodiment.

FIG. 7A is a top plan view of a glass wafer packaging assembly, according to one illustrated embodiment.

FIG. 7B is a cross-sectional view of the glass wafer packaging assembly of FIG. 7A, taken along section line 7B, according to one illustrated embodiment.

FIG. 7C is a cross-sectional view of an individual glass wafer packaging assembly, according to one illustrated embodiment.

FIG. 8 is a flowchart showing a method of producing individual glass wafer packaging assemblies, according to one illustrated embodiment.

FIG. 9 is a cross-sectional illustrative view of several stages of the method of FIG. 8.

### DETAILED DESCRIPTION OF THE INVENTION

In the following description, certain specific details are set forth in order to provide a thorough understanding of various embodiments of the invention. However, one skilled in the art will understand that the embodiments may be practiced without these details. In other instances, well-known structures, equipment and processes associated with integrated circuit fabrication technology, including MEMS fabrication technology and resulting structures have not been shown or described in detail to avoid unnecessarily obscuring the description.

Unless the context requires otherwise, throughout the specification and claims which follow, the word “comprise” and variations thereof, such as, “comprises” and “comprising” are to be construed in an open, inclusive sense, that is as “including, but not limited to.”

Reference throughout this specification to “one embodiment” or “an embodiment” means that a particular feature, structure or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combinable in any suitable manner in one or more embodiments.

The headings provided herein are for convenience only and do not interpret the scope or meaning of the claimed invention.

The processes hereinafter described are not necessarily exhaustive of an integrated circuit manufacturing process. Embodiments can be implemented along with other integrated circuit manufacturing techniques, and only those portions necessary for an understanding of the illustrated embodiments are described.

As an overview, it is desirable to provide protection to MEMS devices integrated on or within a semiconductor substrate such as a MEMS wafer, while allowing the MEMS devices to move freely and without hindering the optical functionality of the MEMS devices (e.g., micro-mirrors).

An embodiment provides the MEMS wafer having a plurality of MEMS devices fabricated thereon and bond pads that are electrically coupled to at least some of the MEMS devices. A wafer cap comprising a unitary structure having a plurality of pockets formed within a plurality of recesses overlies the MEMS wafer. The unitary structure is transmissive to light in an optical portion of the electromagnetic spectrum. The optical portion includes part of a visible portion, an infrared portion or an ultraviolet portion of the electromagnetic spectrum. The pockets are patterned within the wafer cap at locations corresponding to the MEMS devices on the underlying MEMS wafer. The wafer cap with the plurality of pockets may be formed using single shot injection molding. Alternatively, the pockets may be embossed into the wafer cap.

Apertures extend through the unitary structure while being laterally spaced from any adjacent pockets. The apertures may be formed by drilling, anisotropic etching or any other suitable process. The wafer cap may be permanently fixed onto the MEMS wafer such that at least some of the MEMS devices are enclosed within respective cavities formed by the pockets and the MEMS wafer and such that at least some of the apertures are aligned to provide access to the bond pads positioned outside the respective cavities. The wafer cap may be adhesively fixed to the MEMS wafer via a silicon-based adhesive.

A rigid backing layer may be coupled to a backside of the MEMS wafer to provide rigidity to the MEMS wafer. A silicone adhesive may be applied to at least one of the backside of the MEMS wafer or the side of the rigid backing layer being coupled to the MEMS wafer.

The MEMS wafer with the wafer cap fixed thereto and the rigid backing layer coupled thereto are diced to form individual chips having protected MEMS devices that are free to move within their respective cavities.

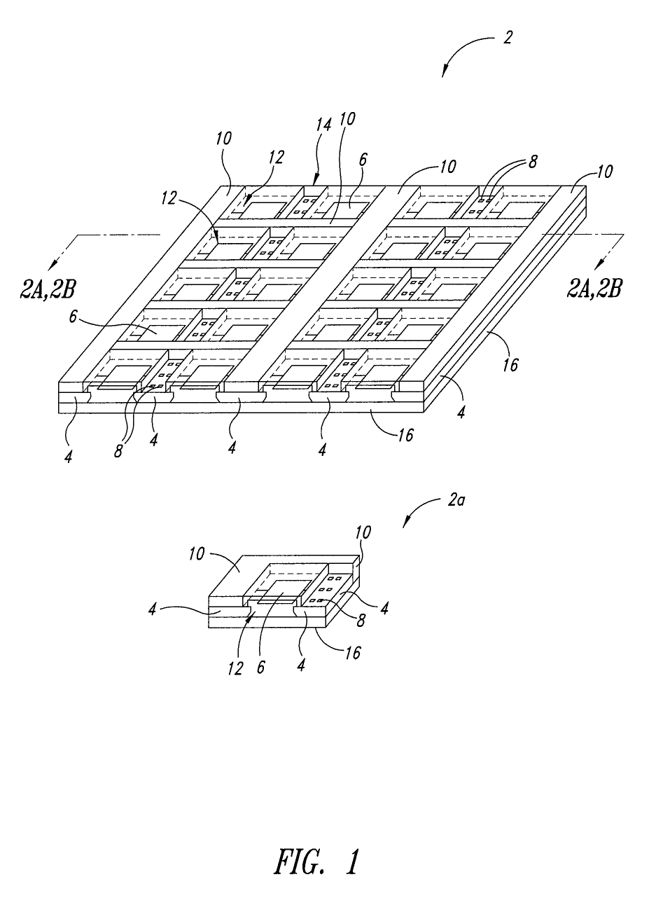

FIG. 1 shows a wafer assembly 2 and a blown up detailed view of a portion of the wafer assembly 2, according to one illustrated embodiment.

The wafer assembly 2, comprises a MEMS substrate 4 having a plurality of MEMS devices 6 and bonding pads 8, and a wafer cap 10 that provides a portion of a protective enclosure or cavity 12 for the MEMS devices 6 while providing access from an exterior 14 of the wafer cap 10 to the bonding pads 8, according to one illustrated embodiment. The wafer assembly 2 may optionally comprise one or more rigid backing layers 16.

As illustrated in FIG. 1, the wafer assembly 2 may be diced along streets and avenues formed in the wafer cap 10, to form individual die assemblies 2a. Such may be used in various electronic devices including, but not limited to, scanners.

The MEMS substrate 4 may comprise a substrate of semiconductor material, for example, silicon (Si) or Gallium Arsenide (GaAs). The MEMS devices 2 may be fabricated on or within the MEMS substrate 4. The MEMS devices 6 may, for example, take the form of micro-mirrors pivotally mounted for oscillation about one or more axes. The MEMS devices 6 may be useful in optical switching to relay light beams between several optical fibers. Electrodes (not shown) are formed adjacent each of the MEMS devices 6 and are used to actuate the MEMS devices 6 so that a suitable position and/or frequency of oscillation is reached, for example, to relay the light beam to a desired optical fiber or to scan an light beam across a target field. The electrodes may be fabricated within the MEMS substrate 4 and may be electrically coupled to extend to respective ones of the bonding pads 8.

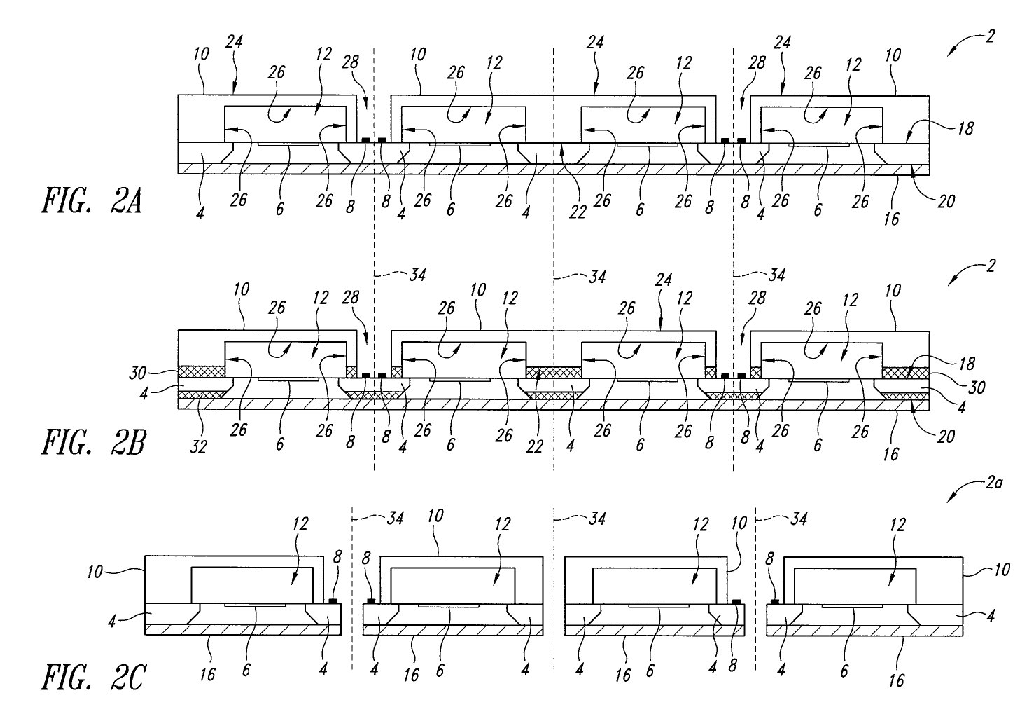

As illustrated in FIG. 2A, the MEMS substrate 4 includes a first face 18 and a second face 20 opposed to the first face 18.

The wafer cap 10 has an inner face 22 and an outer face 24 opposed to the inner face 22. The wafer cap 10 may be a unitary structure having a plurality of pockets 26 formed in the inner face 22. The wafer cap 8 may also have a plurality of apertures 28 extending through the wafer cap 10 from the inner face 22 to the outer face 24. The apertures 28 may be laterally spaced from any adjacent ones of the pockets 26.

The inner face 22 of the wafer cap 10 is secured to the first face 18 of the MEMS substrate 4 with the pockets 26 aligned to enclose respective ones of the MEMS devices 6, and with the apertures 28 are positioned to provide access to the bonding pads 8 from the exterior 14 of the wafer cap 10. In particular, the pockets 26 may cooperate with the first face 18 of the MEMS substrate 4 to form a sealed enclosure or cavity 12 for the MEMS devices 6. The sealed enclosures are sized and dimensioned to provide sufficient space to allow the MEMS devices 6 to move therein, within the operational range of motion of the MEMS devices 6. The sealed enclosure may advantageously prevent contaminants, such as dust or moisture, from damaging the functionality of the MEMS device 6, particularly during dicing and packaging of the wafer assembly 2, as well as during subsequent distribution and/or operation. Thus, the wafer cap 10 may advantageously be permanently fixed to the first face 18 of the MEMS substrate 4, such that the wafer cap 10 is not removed during typical manufacture, distribution or use of the wafer assembly 2 or die assemblies 2a. While illustrated as one MEMS device 6 per pocket 26, some embodiments may have two or more MEMS devices 6 per pocket 26. Additionally, or alternatively, some embodiments may have pockets 26 that do not enclose any MEMS devices 6.

The rigid backing layer 16 may be coupled to the second face 20 of the MEMS substrate 4. The rigid backing layer 16 may be glass (PYREX®), silicon, or a polymer material such as, for example, polycarbonate (XANTAR®) or polymethyl methacrylate (PMMA). The rigid backing layer 16 may have a coefficient of thermal expansion approximately equal to a coefficient of thermal expansion of the wafer cap 10, so as to provide symmetry of expansion, specifically during or after the wafer assembly 2 undergoes a thermal process (discussed further below). In particular, the same polymer material may be used for the rigid backing layer 16 as well as the wafer cap 10.

As illustrated in FIG. 2B, an adhesive 30 may physically couple the inner face 22 of the wafer cap 10 to the first face 18 of the MEMS substrate 4. The adhesive 30 may take the form of a silicone adhesive, an epoxy adhesive, or a UV (Ultraviolet) releasable adhesive that may be removed upon sufficient exposure to UV light. The adhesive 30 may advantageously have mechanical properties similar to that of the MEMS substrate 4. The adhesive may extend over a portion or all of the inner face 22 of the wafer cap 10 and/or over a portion or all of the first face 18 of the MEMS substrate 4.

As also illustrated in FIG. 2B, an adhesive 32 may physically couple the optional rigid backing layer 16 to the second face 20 of the MEMS substrate 4. The adhesive 32 may advantageously take the form of a silicone adhesive.

Depending on the type of adhesive 30, the wafer assembly 2 may undergo a high temperature heat treatment to ensure adequate bonding of the wafer cap 10 to the MEMS substrate 4. High temperature heat treatment results in thermal expansion of the wafer assembly 2. Having the rigid backing layer 16 composed of the same material (e.g., polymer) as the wafer cap 10 provides thermal expansion symmetry, which reduces mechanical stress on the MEMS devices 6.

The wafer cap 10 including the plurality of pockets 26 and apertures 28 are formed prior to being mounted or fixed onto the MEMS substrate 4. This advantageously assures that the MEMS substrate 4 is subjected to a minimal number of processes or acts before the MEMS devices 6 are protected. Forming the wafer cap 10 separately from the MEMS substrate 4 also reduces the total number of non-fabrication processes or acts that the MEMS devices 6, are subjected to, thereby reducing the exposure of the MEMS devices 2 to shocks or small movements. Thus, the wafer cap 10 advantageously covers desired portions of the MEMS wafer 4 in a single act, thereby reducing the likelihood of damaging MEMS devices 6.

In some embodiments, single shot injection molding is used to form the wafer cap 10 with the plurality of pockets 26. In one example, polymer material is fed into an injection molding machine through a hopper. The polymer enters an injection barrel and is then heated to the appropriate melting temperature. Thereafter, the polymer is injected into a mold by a reciprocating screw or a ram injector. The mold may be shaped with the desired pattern of the pockets 26. The polymer is cooled inside the mold so as to form the unitary structure of the wafer cap 10. Alternatively or additionally, the wafer cap 10 is embossed with a desired arrangement of the plurality of pockets 26. The plurality of apertures 28 are formed by at least one of drilling or anisotropic etching the unitary structure prior to fixing the wafer cap 10 to the MEMS substrate 4.

In some embodiments, the wafer cap 10 is transmissive to energy in at least part of an optical portion of the electromagnetic spectrum (e.g., visible, infrared and/or ultraviolet light). This allows, for example, light beams to be relayed to, or from, the MEMS devices 6. For example, the MEMS devices 6 may relay light to appropriate optical fibers with minimal beam loss, or may scan light across another target. Such transmissive properties may be particularly useful when the MEMS devices 6 are implemented in an optical switching or scanning application.

FIG. 2C shows the wafer assembly 2 diced along dicing lines 34 to produce the plurality of individual die assemblies 2a. Each of the die assemblies 2a may comprise at least one of the MEMS device 6 enclosed within the respective cavity 12 formed by one of the pockets 26 and the MEMS substrate 4. The die assemblies 2a further include the bond pads 8 arranged laterally outside the cavity 22 for making electrical couplings with drive circuits or other circuits that are external to the die assembly 2a. The die assemblies 2a may undergo further packaging techniques.

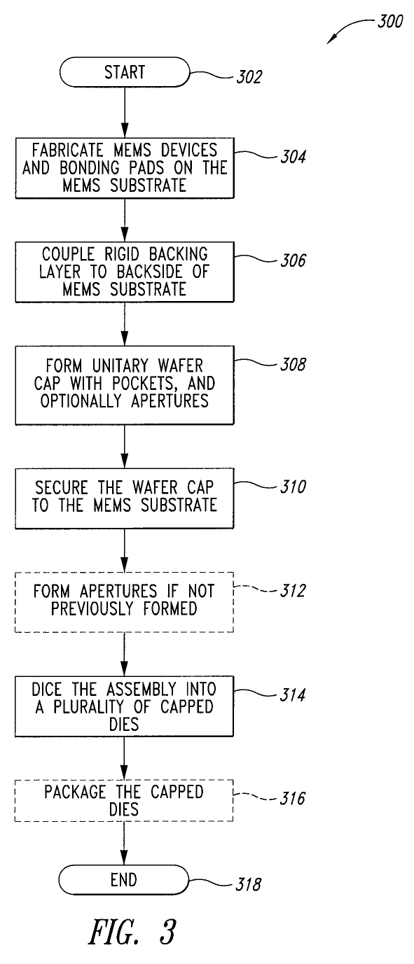

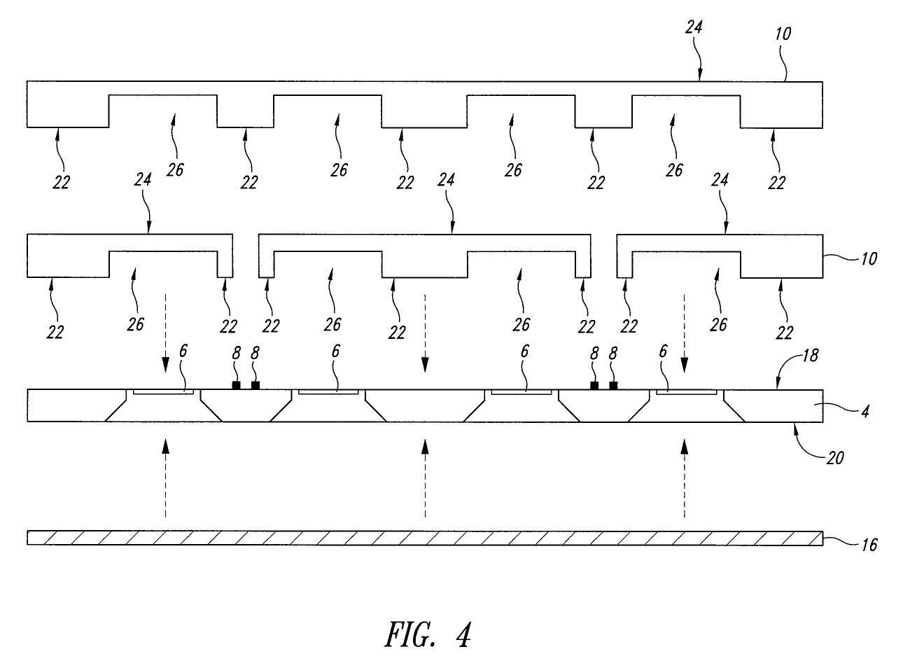

FIG. 3 shows a method 300 of producing die assemblies 2a having MEMS devices 6 and wafer caps 10, according to one illustrated embodiment. FIG. 4 illustrates the method 300 of an exemplary wafer assembly 2.

The method 300 starts at 302, for example in response to a signal indicating the start of a process flow for fabricating the MEMS devices 2. At 304, MEMS devices 6 are formed on the MEMS substrate 4. MEMS device 6 and bonding pad 8 formation typically employs standard fabrication techniques. Such techniques typically include various layering or depositing, masking and/or etching acts, which are commonly practiced in the fabrication arts.

At 306, the rigid backing layer 16 is coupled to the second face 20 of the MEMS substrate 4. As discussed above, a silicone adhesive may be applied to at least one of the second face 20 of the MEMS substrate 4 and/or the rigid backing layer 16 that is being coupled to the second face 20.

At 308, the wafer cap 10 is formed with the plurality of pockets 26, and optionally with the plurality of apertures 28. The unitary structure of the wafer cap 10 together with the pockets 26 may be formed using single shot injection molding. Alternatively and/or additionally, upon formation of the unitary structure, the plurality of pockets 26 may be embossed into the wafer cap 10 and the apertures 28 formed later.

At 310, the wafer assembly 2 is formed by fixing the inner face 22 of the wafer cap 10 to the first face 18 of the MEMS substrate 4 such that at least some of the MEMS devices 6 are enclosed within respective enclosed cavities 12 formed by the pockets 26 and the first face 18 of the MEMS substrate 4. If the apertures 28 have already been formed, at least some of the apertures 28 provide access to the bonding pads 8.

Optionally at 312, the apertures 28 are formed if such have not previously been formed. The apertures 28 may, for example, be formed via masking and anisotropic etching. Such disadvantageously exposes the MEMS devices 6 to additional processes, although the MEMS devices 6 are at this point advantageously protected by the wafer cap 10.

At 314, the wafer assembly 2 is diced along dicing lines 34 to produce the plurality of die assemblies 2a, each with an individual cap. Each of the die assemblies 2a may comprise at least one of the MEMS devices 6 enclosed within the respective cavity 12 formed by one of the pockets 26 and the MEMS substrate 4. The die assembly 2a includes the bonding pads 8 which are advantageously accessible from an exterior of the die assembly 2a to make external couplings, for example for providing drive signals to the MEMS device 6.

At 316, the die assemblies 2a optionally undergo further packaging techniques.

It will be apparent to those of skill in the art, that the acts of the method 300 may be performed in a different order. It will also be apparent to those of skill in the art, that the method 300 omits some acts and/or may include additional acts.

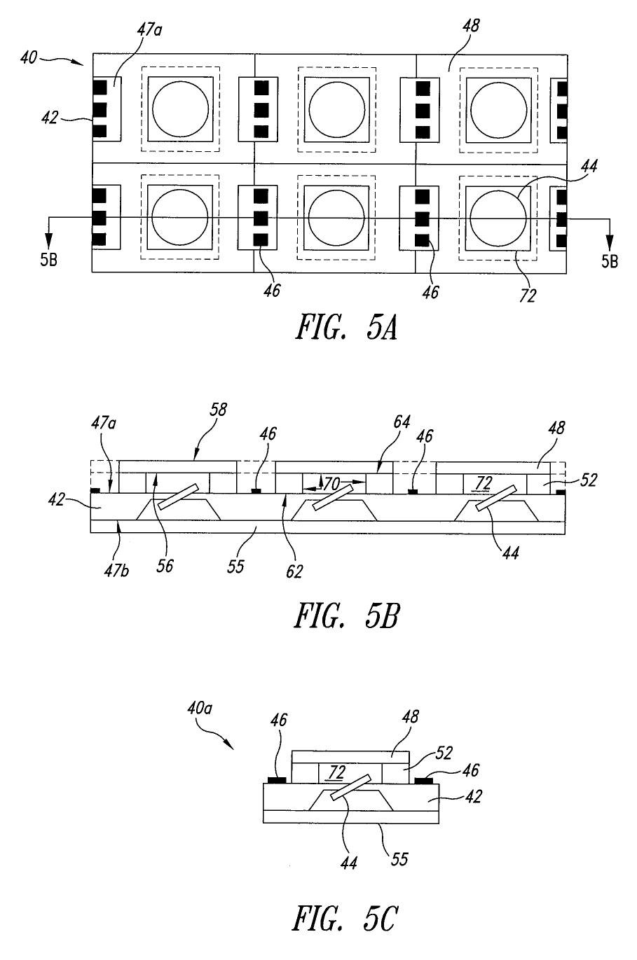

FIGS. 5A and 5B show a wafer packaging assembly 40, according to one illustrated embodiment. FIG. 5C shows an individual assembly 40a, according to one illustrated embodiment.

The wafer packaging assembly 40 comprises a MEMS substrate 42 having a plurality of micro electro-mechanical systems structures (MEMS) 44 and a plurality of bond pads 46 (only two called out in the Figures) positioned on a first face 47a of the MEMS substrate 42 opposed to a second face 47b. The wafer packaging assembly 40 further comprises a wafer cap 48 and a wafer cap support structure 52. At least some of the bond pads 46 are electrically coupled to at least some of the MEMS structures 44. A backside wafer 55 (FIG. 5B) may optionally be coupled to the second face 47b of the MEMS substrate 42.

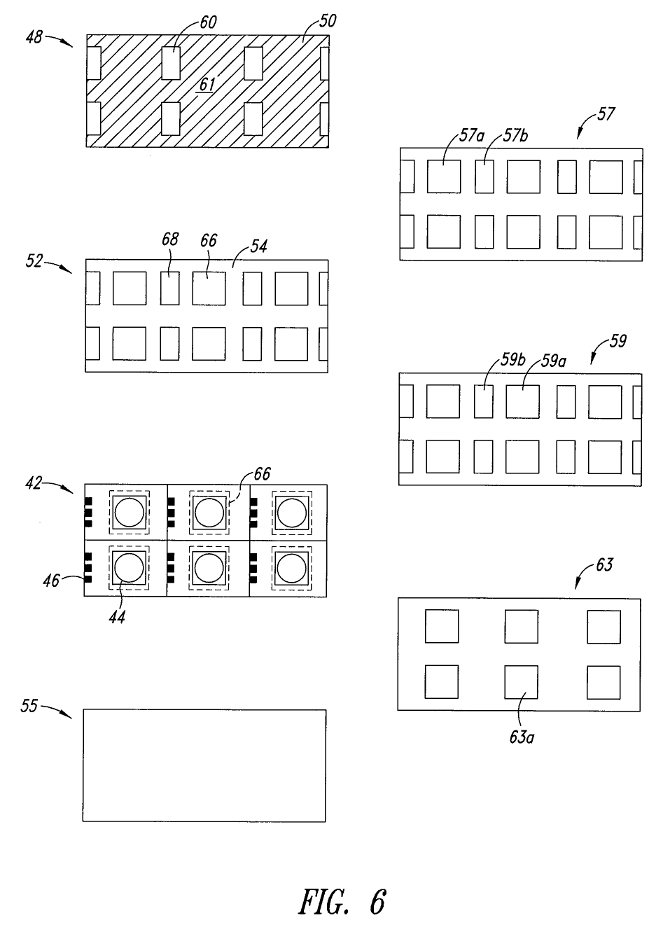

FIG. 6 shows the MEMS substrate 42, the wafer cap 48, the wafer cap support structure 52, a topside wafer-glass cavity seal wafer glue preform 57, a MEMS wafer-topside wafer preform 59 and a backside wafer-MEMS wafer glue preform 63, according to one illustrated embodiment.

The wafer cap 48 may take the form of a unitary glass structure 50 having an inner side 56 and an outer side 58 opposed to the inner side 56. The wafer cap 48 is pre-patterned with a first plurality of apertures 60 extending through the unitary glass structure 50 from the outer side 58 to the inner side 56. The first plurality of apertures 60 may be formed by at least one of drilling or anisotropic etching the unitary glass structure 50. The unitary glass structure 50 may be transmissive to energy in at least part of an optical or visible portion of an electromagnetic spectrum. The unitary glass structure 50 may optionally comprise an antireflective coating 61 coated thereon.

The wafer cap support structure 52 may take the form of a unitary structure 54 having an inner face 62 and an outer face 64 opposed to the inner face 62. The wafer cap support structure 50, which in some embodiments may comprise a silicon wafer, is pre-patterned with a second and a third plurality of apertures 66, 68 extending through the unitary structure 54 from the outer face 64 to the inner face 62. The second and the third plurality of apertures 66, 68 may be formed by at least one of drilling or anisotropic etching the unitary structure 54. The unitary structure 54 may be transmissive to energy in at least part of an optical or visible portion of an electromagnetic spectrum.

The outer face 64 of the wafer cap support structure 52 is fixed to the inner side 56 of the wafer cap 48 such that a plurality of pockets 70 are formed extending between the inner side of the 56 of the wafer cap 48 and the inner face 62 of the wafer cap support structure 50.

The inner face 62 of the wafer cap support structure 50 is fixed to the first face 47a of the MEMS substrate 42 such that the pockets 70 and the MEMS substrate 42 form a plurality of closed cavities 72. The pockets 70 and the MEMS substrate 42 are aligned or registered such that at least some of the MEMS structures 44 are enclosed within respective ones of the cavities 72. The cavities 72 are sized to allow at least a portion of the MEMS structure 44 to move therein. At least some of the third plurality of apertures 68 provides access to the bond pads 46 of the MEMS substrate 42 from an exterior of the wafer cap 48.

In one embodiment, an adhesive is fixedly joining the outer face 64 of the wafer cap support structure 52 to the inner side 56 of the wafer cap 48 while a further adhesive is fixedly joining the inner face 62 of the wafer cap support structure 52 to the first face 47a of the MEMS substrate 42. The adhesive and the further adhesive may be permanent adhesives. In some embodiments the outer face 64 of the wafer cap support structure 52 is fixed to the wafer cap 48 without any intervening structure. Additionally or alternatively the inner face 62 of the wafer cap support structure 52 is fixed to the MEMS substrate 42 without any intervening structure.

The adhesive employed to couple the wafer cap support structure 52 to the wafer cap may take the form of the topside wafer-glass cavity seal wafer glue preform 57. The topside wafer preform 57 may comprise a glue wafer patterned with a first and a second plurality of apertures 57a, 57b sized and patterend to be substantially equivalent to the second and the third plurality of apertures 66, 68 of the wafer cap support structure 52. The topside wafer preform 57 is fixed between the outer face 64 of the wafer cap support structure 52 and the inner side 56 of the wafer cap 48 such that the first and second plurality of apertures 57a, 57b are respectively aligned or in registration with the second and the third plurality of apertures 66, 68 of the wafer cap support structure 52. In one embodiment, the topside wafer preform 57 may be non-conductive.

The further adhesive employed to coupled the wafer cap support structure 52 to the MEMS substrate 42 may take the form of the MEMS wafer-topside wafer preform 59. The MEMS wafer-topside wafer preform 59 may comprise a glue wafer patterned with a first and a second plurality of apertures 59a, 59b sized and patterned to be substantially respectively equivalent to the first and the second plurality of apertures 57a, 57b of the topside wafer preform 57 and the second and third plurality of apertures 66, 68 of the wafer cap support structure 52. The MEMS wafer-topside wafer preform 59 is fixed between the inner face 62 of the wafer cap support structure 52 and the first face 47a of the MEMS substrate 42 such that the first and the second plurality of apertures 59a, 59b are respectively aligned or in registration with the second and the third plurality of apertures 66, 68 of the wafer cap support structure 52. In one embodiment, the MEMS wafer-topside wafer preform 59 may be non-conductive.

The backside wafer 55 may be coupled to the second face 47b of the MEMS substrate 42 via the backside wafer-MEMS wafer glue preform 63. The MEMS wafer glue preform 63 may comprise a glue wafer patterned with a plurality of apertures 63a sized and patterned to be substantially equivalent to the second plurality of apertures 66 of the wafer cap support structure 52. MEMS wafer glue preform 63 is fixed between the second face 47b of the MEMS substrate 42 and the backside wafer 55 such that the plurality of apertures 63a are aligned or in registration with the second plurality of apertures 66 of the wafer cap support structure 52. In one embodiment, the backside wafer-MEMS wafer glue preform 63 may be conductive.

Upon fixing the outer face 64 of the wafer cap support structure 52 to the wafer cap 48 and the inner face 62 of the wafer cap support structure 52 to the MEMS substrate 42, the wafer packaging assembly 40 may be diced to form the plurality of individual assemblies 40a.

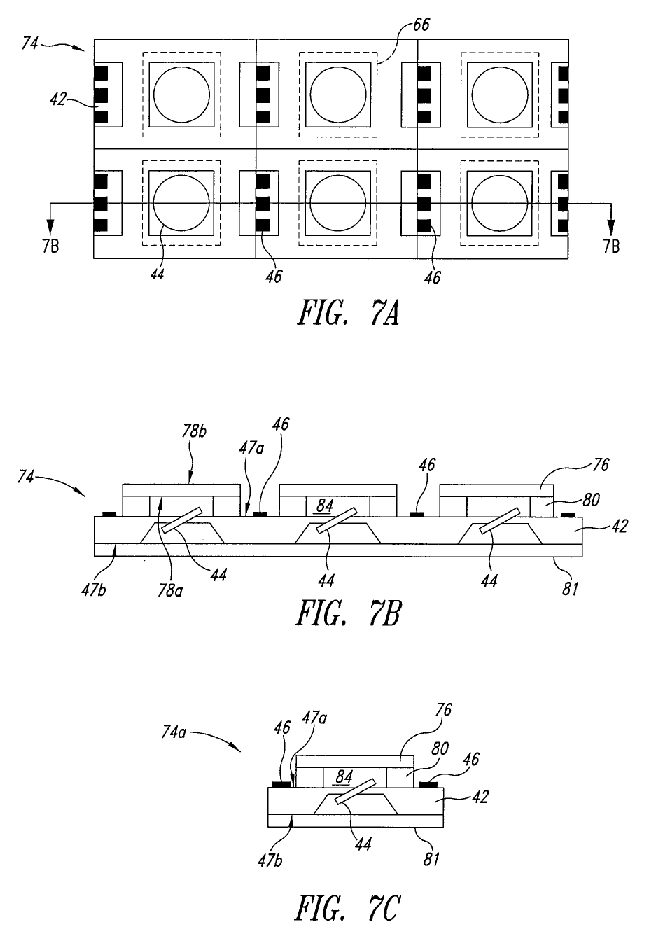

FIGS. 7A and 7B show a glass wafer packaging assembly 74, according to one illustrated embodiment. FIG. 7C shows an individual assembly 74a, according to one illustrated embodiment.

The glass wafer packaging assembly 74 comprises the MEMS substrate 42 having the plurality of micro electro-mechanical systems structures (MEMS) 44 and the plurality of bond pads 46 (only two called out in FIGS. 7A and 7B) positioned on the first face 47a of the MEMS substrate 42 opposed to the second face 47b. The glass wafer packaging assembly 74 further comprises a glass wafer cap 76 and a wafer cap support layer 80. At least some of the bond pads 46 are electrically coupled to at least some of the MEMS structures 44. A glass wafer backing 81 may optionally be coupled to the second face 47b of the MEMS substrate 42.

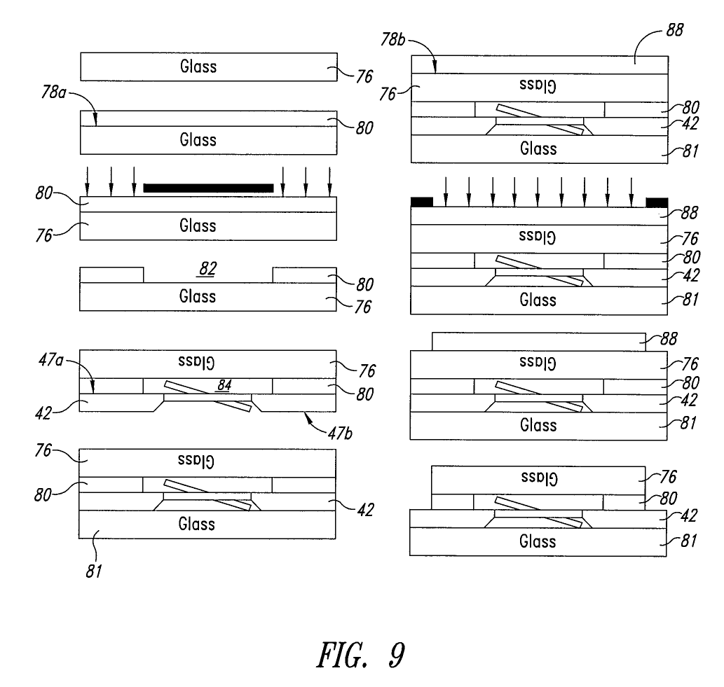

The glass wafer cap 76 includes a first surface 78a and a second surface 78b opposed the first surface 78a. The wafer cap support layer 80 is coupled to the first surface 78a of the glass wafer cap 76. The wafer cap support layer 80 includes a plurality of pockets 82 (shown in FIG. 9) formed therein. The wafer cap support layer 80 is adhered to the first face 47a of the MEMS substrate 42 such that at least some of the MEMS structures 44 are enclosed within respective cavities 84 formed by the pockets 82 and the MEMS substrate 42. The cavities 84 are sufficiently large to allow at least a portion of the MEMS structure 44 to move therein.

In one embodiment, an adhesive fixes the wafer cap support layer 80 to the first surface 78a of the glass wafer cap 76, while a further adhesive fixes the wafer cap support layer 80 to the first face 47a of the MEMS substrate 42. The adhesive and the further adhesive may be permanent adhesives. In some embodiments the wafer cap support layer 80 is fixed to the first surface 78a of the glass wafer cap 76 without any intervening structure. Additionally or alternatively the wafer cap support layer 80 is fixed to the first face 47a of the MEMS substrate 42 without any intervening structure. The glass wafer cap 76 may be transmissive to energy in at least a part of an optical portion of the electromagnetic spectrum.

Both the glass wafer cap 76 and the wafer cap support layer 80 are patterned or selectively removed to expose at least some of the bond pads 46. The assembly 74 may be diced to form the individual assemblies 74a.

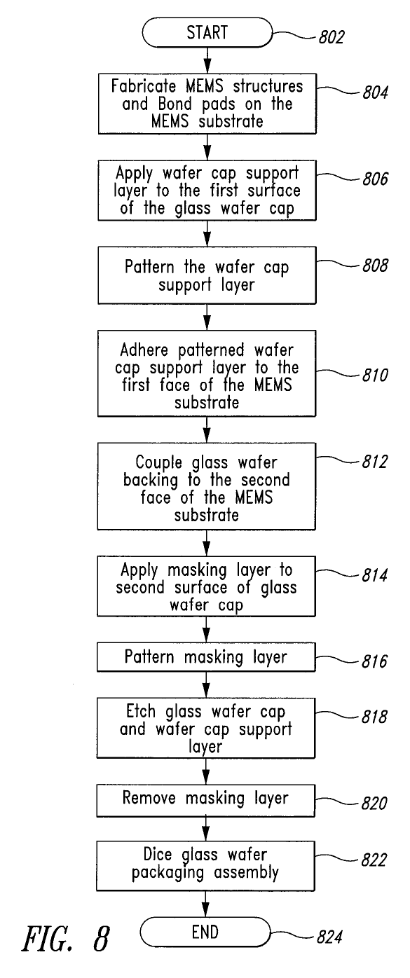

FIG. 8 shows a method 800 of producing the individual assemblies 74a, according to one illustrated embodiment. FIG. 9 illustrates the method 800 of producing an exemplary individual assembly 74a.

The method 800 starts at 802, for example in response to a signal indicating the start of a process flow for fabricating the glass wafer cap packaging assembly 74. At 804, the MEMS structures 44 are formed on the MEMS substrate 42. The MEMS structure 44 and bond pad 46 formation typically employ standard fabrication techniques. Such techniques typically include various layering or depositing, masking and/or etching acts, which are commonly practiced in the fabrication arts. At least some of the bond pads 46 are electrically coupled to at least some of the MEMS structures 44.

At 806, the wafer cap support layer 80 is applied to the first surface 78a of the glass wafer cap 76. The wafer cap support layer 80 may, for example, take the form of a photoresist layer deposited onto the first surface 78a of the glass wafer cap 76. At 808, the wafer cap support layer 80 may be patterned, for example, by selectively removing portions of the photoresist layer via photolithographic techniques which are commonly implemented in the fabrication arts, to form the plurality of pockets 82.

At 810, the patterned wafer cap support layer 80 is adhered to the first face 47a of the MEMS substrate 42 such that at least some of the MEMS structures 44 are enclosed within the respective cavities 84 formed by the pockets 82 and the MEMS substrate 42. The wafer cap support layer 80 may be adhesively fixed to the MEMS substrate 42. Alternatively or additionally the wafer cap support layer 80 may be permanently fixed to the MEMS substrate 42.

At 812, the glass wafer backing 86 is coupled to the second face 47b of the MEMS substrate 42. An adhesive may be applied to at least one of the second face 47b of the MEMS substrate 42 and/or the glass wafer backing 86 that is being coupled to the second face 47b.

At 814, a masking layer 88 is applied to the second surface 78b of the glass wafer cap 76. The masking layer 88 may, for example, take the form of a photoresist layer deposited onto the second surface 78b of the glass wafer cap 76. At 816, the masking layer 88 is patterned to expose portions of the second surface 78b of the glass wafer cap 76 that are in registration with the bond pads 46. For example, the photoresist layer deposited onto the glass wafer cap 76 may be selectively removed via standard photolithographic techniques to expose portions of the second surface 78b of the glass wafer cap 76 that are in registration with the bond pads 46.

At 818, portions of the glass wafer cap 76 and the wafer cap support layer 80 underlying the exposed portions of the second surface 78b of the glass wafer cap 76 are etched to expose the bond pads 46. For example, the portions of the glass wafer cap 76 and the wafer cap support layer 80 underlying the exposed portions of the second surface 78b of the glass wafer cap 76 may be anisotropically etched.

At 820, the masking layer 88 is removed from the second surface 78b of the glass wafer cap 76. The glass wafer cap 76 may be transmissive to energy in at least a part of an optical portion of the electromagnetic spectrum.

At 822, the glass wafer packaging assembly 74 is diced to produce the plurality of individual assemblies 74a, each with an individual glass wafer cap and wafer cap support structure. Each of the individual assemblies 74a may comprise at least one of the MEMS structures 44 enclosed within the respective cavitiy 84 formed by one of the pockets 82 and the MEMS substrate 42. The individual assembly 74a includes the bonding pads 46 which are advantageously accessible from an exterior of the individual assembly 74a to make external couplings, for example for providing drive signals to the MEMS structure 44.

At 824, the individual assemblies 74a optionally undergo further packaging techniques.

It will be apparent to those of skill in the art, that the acts of the method 800 may be performed in a different order. It will also be apparent to those of skill in the art, that the method 800 omits some acts and/or may include additional acts.

All of the above U.S. patents, U.S. patent application publications, U.S. patent applications, foreign patents, foreign patent applications and non-patent publications referred to in this specification and/or listed in the Application Data Sheet, including but not limited to U.S. Provisional Patent Application No. 60/813,097, are incorporated herein by reference, in their entirety.

From the foregoing it will be appreciated that, although specific embodiments of the invention have been described herein for purposes of illustration, various modifications may be made without deviating from the spirit and scope of the invention. Accordingly, the invention is not limited except as by the appended claims.

1. A method of producing a microelectromechanical system (MEMS) device, the method comprising:
providing a MEMS substrate having a first face and a second face opposed to the first face, a plurality of micro electro-mechanical (MEMS) structures, and a plurality of bond pads, at least some of the bond pads electrically coupled to at least some of the MEMS structures;
providing a wafer cap in the form of a unitary structure having an inner face, an outer face opposed to the inner face, a plurality of pockets formed in the inner face and a plurality of apertures extending through the unitary structure from the outer face to the inner face, each of the plurality of apertures laterally spaced from any adjacent ones of the pockets; and
fixing the inner face of the wafer cap to the first face of the MEMS substrate such that at least some of the MEMS structures are enclosed within respective enclosed cavities formed by the pockets and the MEMS substrate, and such that at least some of the apertures of the wafer cap provide access to the bond pads of the MEMS substrate from an exterior of the wafer cap.

2. The method of claim 1 wherein fixing the inner face of the wafer cap to the first face of the MEMS substrate comprises adhesively fixing the inner face of the wafer cap to the first face of the MEMS substrate.

3. The method of claim 1 wherein fixing the inner face of the wafer cap to the first face of the MEMS substrate comprises permanently fixing the inner face of the wafer cap to the first face of the MEMS substrate.

4. The method of claim 1, further comprising
coupling a rigid backing layer to the second face of the MEMS substrate.

5. The method of claim 4 wherein coupling a rigid backing layer to the second face of the MEMS substrate comprises applying a silicone adhesive to the rigid backside layer.

6. The method of claim 4, further comprising
dicing the MEMS substrate with the wafer cap fixed thereto and the rigid backing layer coupled thereto.

7. The method of claim 1, further comprising:
single shot injection molding the wafer cap with the plurality of pockets.

8. The method of claim 1, further comprising:
embossing the plurality of pockets into the unitary structure.

9. The method of claim 1, further comprising:
forming the plurality of apertures by at least one of drilling or anisotropic etching the unitary structure.

10. The method of claim 1 wherein providing a wafer cap comprising a unitary structure comprises providing a unitary structure that is transmissive to energy in at least part of an optical portion of the electromagnetic spectrum.

11. A microelectromechanical system (MEMS) device, comprising:
a MEMS substrate having a first face and a second face opposed to the first face, a plurality of micro electro-mechanical structures, and a plurality of bond pads, at least some of the bond pads electrically coupled to at least some of the MEMS structures; and
a wafer cap in the form of a unitary structure having an inner face, an outer face opposed to the inner face, a plurality of pockets formed in the inner face and a plurality of apertures extending through the unitary structure from the outer face to the inner face, each of the plurality of apertures laterally spaced from any adjacent pockets, wherein the inner face of the wafer cap is fixed to the first face of the MEMS substrate such that at least some of the MEMS mirror structures are enclosed within respective enclosed cavities formed by the pockets and the MEMS substrate, and such that at least some of the apertures of the wafer cap provide access to the bond pads of the MEMS substrate from an exterior of the wafer cap.

12. The device of claim 11, further comprising:
an adhesive fixedly joining the inner face of the wafer cap to the first face of the MEMS substrate.

13. The device of claim 11, further comprising:
a permanent adhesive fixedly joining the inner face of the wafer cap to the first face of the MEMS substrate.

14. The device of claim 11, further comprising:
a permanent adhesive directly joining the inner face of the wafer cap to the first face of the MEMS substrate without any intervening structure.

15. The device of claim 11 wherein the enclosed cavities are sufficiently large to allow at least a portion of the MEMS structure to move therein.

16. The device of claim 11 wherein the wafer cap is transmissive in an optical portion of the electromagnetic spectrum.

17. The device of claim 11 wherein the wafer cap is transmissive in a visible portion of the electromagnetic spectrum.

18. The device of claim 11, further comprising:
a rigid backing layer coupled to the second face of the MEMS substrate.

19. The device of claim 11, further comprising:
a rigid backing layer; and
a silicone adhesive that couples the rigid backing layer to the second face of the MEMS substrate.

20. A microelectromechanical system (MEMS) device, comprising:
a MEMS substrate having a first face and a second face opposed to the first face, a plurality of micro electro-mechanical oscillateable micro-mirror structures, and a plurality of bond pads, at least some of the bond pads electrically coupled to at least some of the MEMS structures; and
a wafer cap in the form of a unitary structure transmissive of light in an optical portion of the electromagnetic spectrum and having an inner face, an outer face opposed to the inner face, a plurality of pockets formed in the inner face and a plurality of apertures extending through the unitary structure from the outer face to the inner face, each of the plurality of apertures laterally spaced from any adjacent pockets, wherein the inner face of the wafer cap is fixed to the first face of the MEMS substrate such that at least some of the MEMS micro-mirror structures are enclosed within respective enclosed cavities formed by the pockets and the MEMS substrate with sufficient space to oscillate therein, and such that at least some of the apertures of the wafer cap provide access to the bond pads of the MEMS substrate from an exterior of the wafer cap.

21. The device of claim 21 wherein the optical portion of the electromagnetic spectrum includes part of a visible portion, an infrared portion or an ultraviolet portion of the electromagnetic spectrum.

22. The device of claim 9, further comprising:
a backing layer adjoined to the second face of the MEMS substrate, the backing layer selected from the group consisting of silicon, polymers, and glass, and wherein the backing layer has a coefficient of thermal expansion approximately equal to a coefficient of thermal expansion of the wafer cap.

23. The device of claim 22 wherein the polymer is one of polycarbonate or polymethyl methacrylate (PMMA).

24. A method of producing a microelectromechanical system (MEMS) device, the method comprising:
providing a MEMS substrate having a first face and a second face opposed to the first face, a plurality of micro electro-mechanical (MEMS) structures, and a plurality of bond pads, at least some of the bond pads electrically coupled to at least some of the MEMS structures;
providing a wafer cap in the form of a unitary glass structure having an inner side, an outer side opposed the inner side, the wafer cap pre-patterned with a first plurality of apertures extending through the unitary glass structure from the outer side to the inner side;
providing a wafer cap support structure in the form of a unitary structure having an inner face, an outer face opposed the inner face, the wafer cap support structure pre-patterned with a second and a third plurality of apertures, the second and the third plurality of apertures extending through the unitary structure from the outer face to the inner face;
fixing the outer face of the wafer cap support structure to the inner side of the wafer cap such that a plurality of pockets are formed extending between the inner side of the wafer cap and the inner face of the wafer cap support structure; and
fixing the inner face of the wafer cap support structure to the first face of the MEMS substrate such that at least some of the MEMS structures are enclosed within respective cavities formed by the pockets and the MEMS substrate, and such that at least some of the first and third apertures provide access to the bond pads of the MEMS substrate from an exterior of the wafer cap.

25. The method of claim 24 wherein fixing the outer face of the wafer cap support structure to the inner side of the wafer cap comprises adhesively fixing the outer face of the wafer cap support structure to the inner side of the wafer cap.

26. The method of claim 24 wherein fixing the inner face of the wafer cap support structure to the first face of the MEMS substrate comprises adhesively fixing the inner face of the wafer cap support structure to the first face of the MEMS substrate.

27. The method of claim 24, further comprising:
coupling a backside wafer to the second face of the MEMS substrate.

28. The method of claim 27 wherein coupling the backside wafer to the second face of the MEMS substrate comprises applying a silicone adhesive to the backside wafer.

29. The method of claim 24, further comprising:
dicing the MEMS substrate with the wafer cap support structure fixed thereto.

30. The method of claim 24, further comprising:
forming the first plurality of apertures by at least one of drilling or anisotropic etching the unitary glass structure; and
forming the second and third plurality of apertures by at least one of drilling or anisotropic etching the unitary structure.

31. The method of claim 24 wherein providing the wafer cap comprises providing a unitary glass structure that is transmissive to energy in at least part of an optical portion of the electromagnetic spectrum.

32. The method of claim 24 wherein providing the wafer cap support structure comprises providing a unitary structure that is transmissive to energy in at least part of an optical portion of the electromagnetic spectrum.

33. A microelectromechanical system (MEMS) device, comprising:
a MEMS substrate having a first face and a second face opposed to the first face, a plurality of micro electro-mechanical (MEMS) structures, and a plurality of bond pads, at least some of the bond pads electrically coupled to at least some of the MEMS structures;
a wafer cap in the form of a unitary glass structure having an inner side, an outer side opposed the inner side, the wafer cap pre-patterned with a first plurality of apertures extending through the unitary glass structure from the outer side to the inner side;
a wafer cap support structure in the form of a unitary structure having an inner face, an outer face opposed the inner face, the wafer cap support structure pre-patterned with a second and a third plurality of apertures, the second and the third plurality of apertures extending through the unitary structure from the outer face to the inner face; and
the outer face of the wafer cap support structure fixed to the inner side of the wafer cap to form a plurality of pockets extending between the inner side of the wafer cap and the inner face of the wafer cap support structure, the inner face of the wafer cap support structure fixed to the first face of the MEMS substrate such that the pockets and the MEMS substrate for a plurality of closed cavities such that at least some of the MEMS structures are enclosed within respective ones of cavities formed by the pockets and the MEMS substrate, and such that at least some of the first and the third apertures provide access to the bond pads of the MEMS substrate from an exterior of the wafer cap.

34. The device of claim 33, further comprising:
an antireflective coating coated on the unitary glass structure.

35. The device of claim 33, further comprising:
an adhesive fixedly joining the outer face of the wafer cap support structure to the inner side of the wafer cap; and
an adhesive fixedly joining the inner face of the wafer cap support structure to the first face of the MEMS substrate.

36. The device of claim 33, further comprising:
a permanent adhesive fixedly joining the outer face of the wafer cap support structure to the inner side of the wafer cap; and
a permanent adhesive fixedly joining the inner face of the wafer cap support structure to the first face of the MEMS substrate.

37. The device of claim 33, further comprising:
a permanent adhesive fixedly joining the outer face of the wafer cap support structure to the inner side of the wafer cap without any intervening structure; and
a permanent adhesive fixedly joining the inner face of the wafer cap support structure to the first face of the MEMS substrate without any intervening structure.

38. The device of claim 33 wherein the cavities are sufficiently large to allow at least a portion of the MEMS structure to move therein.

39. The device of claim 33 wherein the wafer cap is transmissive in an optical portion of the electromagnetic spectrum.

40. The device of claim 33 wherein the wafer cap is transmissive in a visible portion of the electromagnetic spectrum.

41. The device of claim 33, further comprising:
a backside wafer coupled to the second face of the MEMS substrate.

42. A method of producing a microelectromechanical system (MEMS) device, the method comprising:
providing a MEMS substrate having a first face and a second face opposed to the first face, a plurality of micro electro-mechanical (MEMS) structures, and a plurality of bond pads, at least some of the bond pads electrically coupled to at least some of the MEMS structures;
providing a glass wafer cap having a first and a second surface;
applying a wafer cap support layer to the first surface of the glass wafer cap;
patterning the wafer cap support layer to form a plurality of pockets;
adhering the wafer cap support layer to the first face of the MEMS substrate such that at least some of the MEMS structures are enclosed within respective cavities formed by the pockets and the MEMS substrate;
applying a masking layer to the second surface of the glass wafer cap;
patterning the masking layer to expose portions of the second surface of the glass wafer cap that are in registration with the bond pads; and
etching portions of the glass wafer cap and the wafer cap support layer underlying the exposed portions of the glass wafer cap to expose the bond pads.

43. The method of claim 42 wherein applying the wafer cap support layer to the first surface of the glass wafer cap comprises depositing a photoresist layer onto the first surface of the glass wafer cap.

44. The method of claim 43 wherein patterning the wafer cap support layer comprises selectively removing portions of the photoresist layer via photolithographic techniques.

45. The method of claim 42 wherein adhering the wafer cap support layer to the first face of the MEMS substrate comprises adhesively fixing the wafer cap support layer to the first face of the MEMS substrate.

46. The method of claim 42 wherein adhering the wafer cap support layer to the first face of the MEMS substrate comprises permanently fixing the wafer cap support layer to the first face of the MEMS substrate.

47. The method of claim 42 wherein applying the masking layer to the second surface of the glass wafer cap comprises depositing a photoresist layer onto the second surface of the glass wafer cap.

48. The method of claim 47 wherein patterning the masking layer comprises selectively removing portions of the photoresist layer via photolithographic techniques to expose portions of the second surface of the glass wafer cap that are in registration with the bond pads.

49. The method of claim 42 wherein etching portions of the glass wafer cap and the wafer cap support layer comprises anisotropic etching of the glass wafer cap and the wafer cap support layer underlying the exposed portions of the glass wafer cap and exposing the bond pads.

50. The method of claim 42, further comprising:
removing the masking layer from the second surface of the glass wafer cap.

51. The method of claim 42 wherein providing a glass wafer cap comprises providing a glass wafer cap that is transmissive to energy in at least a part of an optical portion of the electromagnetic spectrum.

52. The method of claim 42, further comprising:
coupling a glass wafer backing to the second face of the MEMS substrate.

53. The method of claim 42, further comprising:
dicing the MEMS substrate with the glass wafer cap fixed thereto.

54. A microelectromechanical system (MEMS) device, comprising:
a MEMS substrate having a first face and a second face opposed to the first face, a plurality of micro electro-mechanical (MEMS) structures, and a plurality of bond pads, at least some of the bond pads electrically coupled to at least some of the MEMS structures;
a glass wafer cap having a first surface and a second surface opposed the first surface;
a wafer cap support layer coupled to the first surface of the glass wafer cap and having a plurality of pockets formed therein;
the wafer cap support layer adhered to the first face of the MEMS substrate such that at least some of the MEMS structures are enclosed within respective cavities formed by the pockets and the MEMS substrate; and
a masking layer coupled to the second surface of the glass wafer cap, the masking layer patterned to expose portions of the second surface of the glass wafer cap that are in registration with the bond pads, the bond pads being exposed upon etching portions of the glass wafer cap and the wafer cap support layer underlying the exposed portions of the second surface of the glass wafer cap.

55. The device of claim 54 wherein the wafer cap support layer coupled to the first surface of the glass wafer cap comprises a photoresist layer deposited onto the first surface of the glass wafer cap.

56. The device of claim 55 wherein the plurality of pockets comprises selectively removed portions of the photoresist layer via photolithographic techniques.

57. The device of claim 54, further comprising:
an adhesive fixedly joining the wafer cap support layer to the first surface of the glass wafer cap; and
an adhesive fixedly joining the wafer cap support layer to the first face of the MEMS substrate.

58. The device of claim 54, further comprising:
a permanent adhesive fixedly joining the wafer cap support layer to the first surface of the glass wafer cap; and
a permanent adhesive fixedly joining the wafer cap support layer to the first face of the MEMS substrate.

59. The device of claim 54, further comprising:
a permanent adhesive directly joining the wafer cap support layer to the first surface of the glass wafer cap without any intervening structure; and
a permanent adhesive directly joining the wafer cap support layer to the first face of the MEMS substrate without any intervening structure.

60. The device of claim 54 wherein the cavities are sufficiently large to allow at least a portion of the MEMS structure to move therein.

61. The device of claim 54 wherein the masking layer comprises a photoresist layer, the photoresist layer being selectively removed to expose portions of the second surface of the glass wafer cap that are in registration with the bond pads.

62. The device of claim 54 wherein the glass wafer cap is transmissive to energy in at least a part of an optical portion of the electromagnetic spectrum.

63. The device of claim 54, further comprising:
a glass wafer backing coupled to the second face of the MEMS substrate.
